(19) United States
(12) Patent Application Publication
(10) Pub. No.: US 2024/0288265 A1
(43) Pub. Date: Aug. 29, 2024

(54) SEMICONDUCTOR MEASUREMENT APPARATUS

(71) Applicant: SAMSUNG ELECTRONICS CO., LTD., Suwon-si (KR)

(72) Inventors: Jinyong Kim, Suwon-si (KR); Yasuhiro Hidaka, Yokohama-shi (JP); Wookrae Kim, Suwon-si (KR); Ingi Kim, Suwon-si (KR); Jinseob Kim, Suwon-si (KR)

(73) Assignee: SAMSUNG ELECTRONICS CO., LTD., Suwon-si (KR)

(21) Appl. No.: 18/372,391

(22) Filed: Sep. 25, 2023

(30) Foreign Application Priority Data
Feb. 24, 2023 (KR) 10-2023-0025018

(51) Int. Cl. G01B 11/02

(52) U.S. Cl. CPC G01B 11/02; G01B 2210/56

(57) ABSTRACT

Provided is a semiconductor measurement apparatus that includes: a lighting unit comprising a light source, and a light modulator configured to decompose a light output by the light source into a plurality of wavelength bands and generate an output light of at least two selected wavelength bands; a first optical unit comprising an illumination polarizing element disposed in a path of the output light; a second optical unit comprising a beam splitter, an objective lens configured to allow light having passed through the first optical unit to be incident onto a sample, and a self-interference generator disposed on a path of a reflected light; a sensor configured to output an original image representing an interference pattern of light having passed through the self-interference generator; and a controller configured to process the original image and determine a selected critical dimension of a structure included in the sample.

### CROSS-REFERENCE TO RELATED APPLICATION(S)

This application is based on and claims priority under 35 U.S.C. § 119 to Korean Patent Application No. 10-2023-0025018 filed on Feb. 24, 2023 in the Korean Intellectual Property Office, the disclosure of which is incorporated herein by reference in its entirety.

### BACKGROUND

### 1. Field

The disclosure relates to a semiconductor measurement apparatus.

### 2. Description of Related Art

A semiconductor measurement apparatus is a device for measuring a critical dimension of a structure in a sample including a structure formed by a semiconductor process, and in general, critical dimensions and the like may be measured using ellipsometry. In ellipsometry, light is irradiated onto a sample at fixed azimuth and incident angles, and a critical dimension of a structure included in a region of the sample to which light is irradiated may be determined using a spectral distribution of light reflected from the sample. As the critical dimension of a structure formed by a semiconductor process gradually decreases, the influence of changes in other critical dimensions, other than the critical dimension to be measured, on the spectral distribution may increase. As a result, a problem may occur in which a critical dimension to be measured cannot be accurately determined based on the spectral distribution obtained from the ellipsometry.

### SUMMARY

According to an aspect of the disclosure, a semiconductor measurement apparatus includes: a lighting unit comprising a light source, and a light modulator configured to decompose a light output by the light source into a plurality of wavelength bands and generate an output light in which light of at least two selected wavelength bands is arranged in one direction: a first optical unit comprising at least one illumination polarizing element disposed in a path of the output light: a second optical unit comprising a beam splitter, an objective lens configured to allow light having passed through the first optical unit to be incident onto a sample, and a self-interference generator disposed on a path of a reflected light from the sample: a sensor disposed on a rear end of the second optical unit and configured to output an original image representing an interference pattern of light having passed through the self-interference generator; and a controller configured to process the original image and determine a selected critical dimension from among a plurality of critical dimensions of a structure included in the sample.

The self-interference generator may include a Nomarski prism and at least one polarizer sequentially disposed in the path of the reflected light.

The light modulator may include an optical member configured to decompose the light output by the light source into the plurality of wavelength bands, and a spatial light modulator configured to generate the output light by passing the light having passed through only a selected partial area of the optical member, and the optical member may be further configured to emit the output light generated by the spatial light modulator to the first optical unit.

The optical member may include at least one of a prism or a grating structure.

The light modulator may include a cylinder lens and a focusing lens disposed between the optical member and the spatial light modulator.

The light modulator may include a first cylinder lens disposed between the optical member and the focusing lens, and a second cylinder lens disposed between the focusing lens and the spatial light modulator.

The spatial light modulator may include at least one of a digital micromirror device (DMD), a liquid crystal on silicon (LCos), or a liquid crystal display (LCD).

The original image may represent the interference pattern generated from the light of the at least two selected wavelength bands and may include a plurality of regions arranged along the one direction.

The controller may be further configured to convert each of the plurality of regions into a frequency domain and acquire spectral distribution data in which at least one peak appears due to interference of polarization components included in light of the at least two selected wavelength bands, and the controller may be further configured to obtain intensity difference and phase difference of the polarization components included in light of each of the at least two selected wavelength bands by inversely frequency transforming the spectral distribution data of each of the plurality of regions.

The objective lens may have a numerical aperture of at least 0.8 and less than 1.0.

The sensor may be an image sensor, and a surface of the image sensor may be located in a conjugation position of a back focal plane of the objective lens.

The light output from the light source may include a wavelength band from ultraviolet to infrared.

According to an aspect of the disclosure, a semiconductor measurement apparatus includes: a lighting unit configured to generate an output light in which light of at least two selected wavelength bands are arranged in a first direction: a first optical unit disposed on a path of the output light: a second optical unit comprising an objective lens disposed on a path of an incident light having passed through the first optical unit and a path of a reflected light in which a sample reflects the incident light: an image sensor configured to generate a self-interference image representing an interference pattern of light having passed through the second optical unit; and a controller configured to measure a selected critical dimension among a plurality of critical dimensions of a structure included in the sample by using the self-interference image, wherein the controller determines the selected wavelength bands of the output light and an arrangement order of the selected wavelength bands in the first direction, based on the selected critical dimension.

The lighting unit may include a light source, an optical member refracting and outputting light output from the light source, and a spatial light modulator having a plurality of optical regions reflecting or transmitting an output of the optical member therethrough.

The controller may be further configured to determine the selected wavelength bands and the arrangement order of the selected wavelength bands by activating a selected area of a portion of the plurality of optical regions and deactivating an unselected area.

The controller may be further configured to determine the selected wavelength bands and the arrangement order of the selected wavelength bands based on a relationship between coordinates defined in a plane, perpendicular to an optical axis of the reflected light, and sensitivity to the plurality of critical dimensions.

The coordinates may be defined by an angle of incidence and an angle of reflection of the reflected light.

According to an aspect of the disclosure, a semiconductor measurement apparatus includes: a lighting unit configured to generate an output light based on sensitivity data obtained by matching wavelength bands of light, an incident angle of light, and an azimuth angle of light with a sensitivity of a critical dimension: an image sensor configured to generate an original image based on receiving reflected light in which the output light is reflected from a target region of a sample; and a controller configured to obtain optical information of polarization components included in the reflected light from each of a plurality of regions in the original image, and determine a selected critical dimension among a plurality of critical dimensions of structures included in the target region based on the optical information.

The plurality of regions may represent an interference pattern of polarization components included in light of a plurality of selected wavelength bands included in the output light.

The controller may be further configured to obtain an intensity difference and a phase difference of the polarization components included in the light of the plurality of selected wavelength bands, as the optical information.

### BRIEF DESCRIPTION OF THE DRAWINGS

The above and other aspects, features, and advantages of certain embodiments of the present disclosure will be more apparent from the following description, taken in conjunction with the accompanying drawings, in which:

FIG. 1 is a schematic diagram of a semiconductor measurement apparatus according to an embodiment:

FIGS. 2A-2D are diagrams provided to describe an operating method of a semiconductor measurement apparatus according to an embodiment:

FIG. 3 and FIG. 4 are flowcharts provided to illustrate a measurement method using a semiconductor measurement apparatus according to an embodiment:

FIG. 5 is a block diagram simply illustrating a lighting unit included in a semiconductor measurement apparatus according to an embodiment:

FIG. 6 is a schematic diagram of a semiconductor measurement apparatus according to an embodiment:

FIGS. 7A-7C are diagrams provided to illustrate operations of a semiconductor measurement apparatus according to an embodiment:

FIG. 8 is a diagram simply illustrating incident light generated by a semiconductor measurement apparatus according to an embodiment:

FIG. 9 is a diagram provided to illustrate the operation of a semiconductor measurement apparatus according to an embodiment:

FIG. 10 is a diagram illustrating a self-interference generator included in a semiconductor measurement apparatus according to an embodiment.

FIGS. 11A and 11B are diagrams illustrating original images acquired by a semiconductor measurement apparatus according to an embodiment:

FIGS. 12, 13, 14, 15, and 16 are diagrams provided to illustrate the operation of a semiconductor measurement apparatus according to an embodiment;

FIG. 17 and FIG. 18 are diagrams provided to illustrate the operation of a semiconductor measurement apparatus according to an embodiment:

FIGS. 19, 20, and 21 are diagrams provided to describe a light control method of a semiconductor measurement apparatus according to an embodiment; and

FIG. 22 and FIG. 23 are diagrams provided to illustrate the operation of a semiconductor measurement apparatus according to an embodiment.

### DETAILED DESCRIPTION

Hereinafter, embodiments of the present disclosure will be described in detail with reference to the accompanying drawings, where similar reference characters denote corresponding features consistently throughout. The embodiments described herein are example embodiments, and thus, the disclosure is not limited thereto and may be realized in various other forms.

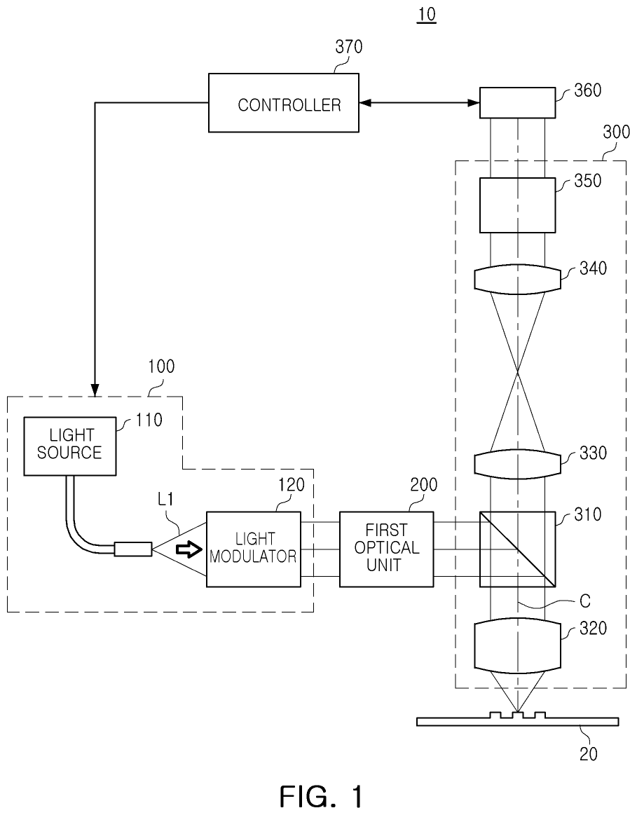

FIG. 1 is a schematic diagram of a semiconductor measurement apparatus according to an embodiment.

Referring to FIG. 1, a semiconductor measurement apparatus 10 may be a device using an ellipsometry. As illustrated in FIG. 1, the semiconductor measurement apparatus 10 may include a lighting unit 100, a first optical unit 200, a second optical unit 300, an image sensor 360, a controller 370, and the like. The semiconductor measurement apparatus 10 may generate an image by receiving light irradiated to a sample 20 by the lighting unit 100 and reflected from the sample 20, and may measure a critical dimension of a structure included in the sample 20 by analyzing the image.

The lighting unit 100 may include a light source 110, a light modulator 120, and the like. In an embodiment, light source 110 outputs light incident on the sample 20, and the light emitted from the light source 110 may be light including a wavelength band of ultraviolet rays to a wavelength range of infrared rays, or may be monochromatic light having a specific wavelength. The light modulator 120 may select two or more selected wavelength bands from the light emitted by the light source 110 and arrange the light of the selected wavelength bands in one direction in a plane perpendicular to the optical axis C to generate output light. Accordingly, light of different selected wavelength bands may be incident to the sample 20 while traveling at different positions in a plane perpendicular to the optical axis C.

The first optical unit 200 may include a plurality of optical elements that pass output light output from the lighting unit 100. For example, the first optical unit 200 may include at least one lighting polarization element, at least one lighting lens, and the like. The first optical unit 200 may also include a reflection mirror that changes the propagation direction of the light having passed through the lighting polarization element and the illumination lens.

The second optical unit 300 may include a beam splitter 310, an objective lens 320, a first light receiving lens 330, a second light receiving lens 340, a self-interference generator 350, and the like. The beam splitter 310 may reflect a portion of the light received from the first optical unit 200 and transmit a portion of the light. The light reflected by the beam splitter 310 is incident on the objective lens 320, and the light passing through the objective lens 320 may be incident on the sample 20 as incident light. For example, the incident light may pass through the objective lens 320 and be incident on the sample 20 to be focused on a target region of the sample 20.

At least some of the incident light passing through the objective lens 320 is reflected from the target region of the sample 20, and the objective lens 320 may receive the reflected light reflected from the target region of the sample 20. As illustrated in FIG. 1, respective optical axes C of the incident light and the reflected light may be perpendicular to the surface of the sample 20.

The reflected light reflected from the sample 20 sequentially passes through the objective lens 320, the beam splitter 310, the first light receiving lens 330, the second light receiving lens 340, and the self-interference generator 350, to be incident on the image sensor 360. The light passing through the beam splitter 310 is condensed by the first light receiving lens 330 and the second light receiving lens 340 to form an image, and then, the light may be incident to the self-interference generator 350.

The self-interference generator 350 may include a beam displacer that decomposes light into a first polarization component and a second polarization component, a polarizer, and the like. For example, the beam displacer may separate the light reflected from the sample 20 into P-polarized components and S-polarized components that are perpendicular to each other. The P-polarized component and the S-polarized component form a focus on the surface of the image sensor 360 after passing through the analyzer, and thus the image sensor 360 may generate an original image representing an interference pattern of light.

A plurality of polarization components generated by the self-interference generator 350 may be incident to the image sensor 360 while interfering with each other, and as a result, the original image generated by the image sensor 360 may generate a self-interference image representing an interference pattern of light as the original image. In an embodiment, the lighting unit 100 emits output light in a form in which two or more different selected wavelength bands are arranged in one direction, and the original image output by the image sensor 360 may include a plurality of regions arranged in one direction. Each of the plurality of regions may represent interference patterns in light of each of the selected wavelength bands.

For example, the first region of the original image may represent an interference pattern generated when light in a first selected wavelength band is reflected from the sample 20 and passes through the self-interference generator 350. On the other hand, the second region of the original image may represent an interference pattern generated while light of the second selected wavelength band is reflected from the sample 20 and passes through the self-interference generator 350. Accordingly, one original image may represent interference patterns in light of the respective different selected wavelength bands, and the original image may be defined as multiple interference images.

The controller 370 may process the original image to determine a selected critical dimension among critical dimensions of structures included in the area to which light is irradiated in the sample 20. In an embodiment, the controller 370 may obtain optical information such as intensity difference and phase difference of polarization components included in light of the respective selected wavelength regions by frequency-converting each of a plurality of regions included in the original image.

Therefore, the controller 370 may simultaneously acquire the intensity difference and phase difference of polarization components after the light of a plurality of selected wavelength bands is reflected from the sample 20 by analyzing one original image obtained in one shot. In addition, by irradiating the sample 20 with incident light using the objective lens 320 having a large numerical aperture, the intensity difference and phase difference of polarization components of the light irradiated to the sample 20 at various azimuthal and incident angles may be measured and obtained simultaneously. Therefore, despite the interaction between the critical dimensions of the structures, optical information required to accurately determine the selected critical dimension may be obtained within a short time, and the time required to measure the selected critical dimension may be shortened.

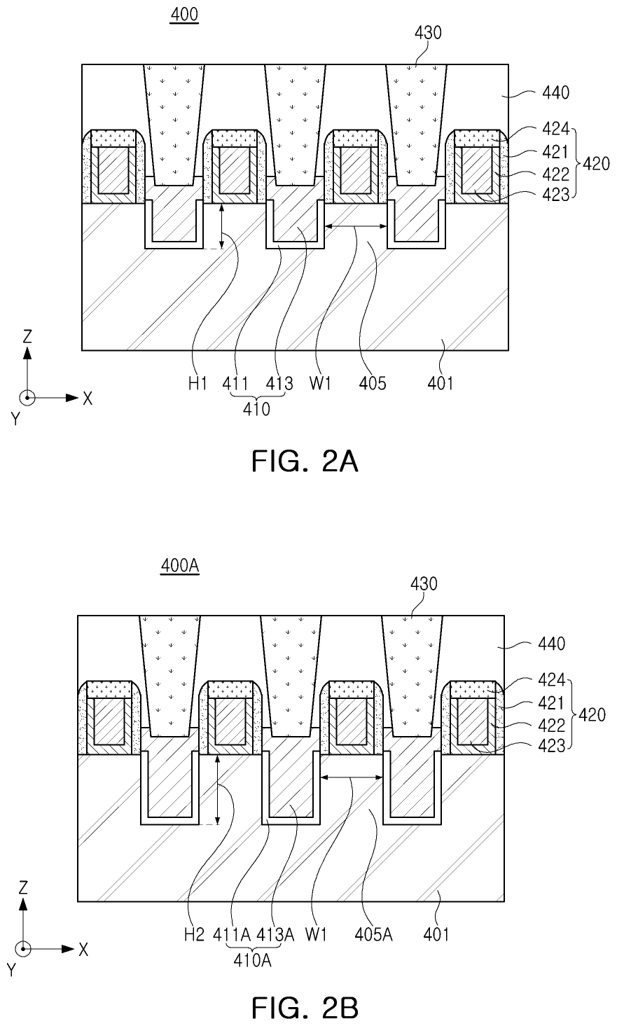

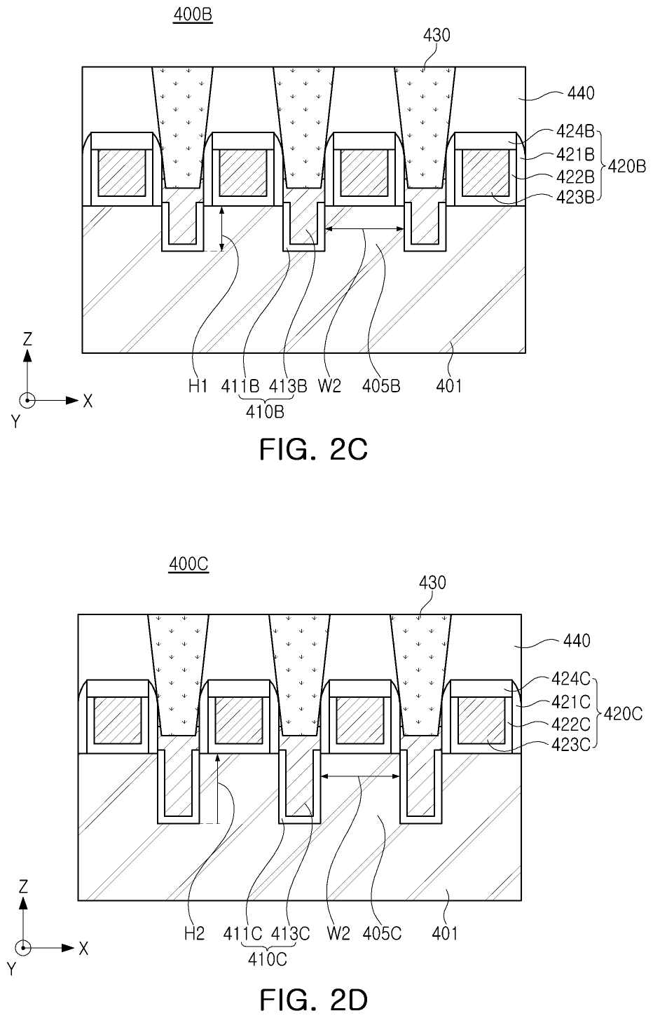

FIGS. 2A-2D are views illustrating a method of operating a semiconductor measurement apparatus according to an embodiment.

FIGS. 2A-2D may be diagrams schematically illustrating partial regions of semiconductor devices 400 and 400A-400C corresponding to samples of a semiconductor measurement apparatus. The semiconductor devices 400 and 400A-400C may include a plurality of semiconductor elements.

Referring first to FIG. 2A, the semiconductor device 400 may include a substrate 401, source/drain regions 410, gate structures 420, source/drain contacts 430, an interlayer insulating layer 440, and the like. However, in this case, a partial region of the semiconductor device 400 is illustrated, and the semiconductor device 400 may further include wiring patterns, gate contacts, a plurality of pad regions, guard patterns, and the like.

The substrate 401 may include a semiconductor material, and a plurality of fin structures 405 protruding in a Z-axis direction perpendicular to an upper surface of the substrate 401 may be formed on the substrate 401. The plurality of fin structures 405 are connected to the source/drain regions 410 at both sides in the X-axis direction, and may contact the gate structures 420 in the Y-axis direction and the Z-axis direction. Each of the plurality of fin structures 405 may have a predetermined height and width, and may provide a channel region.

Each of the source/drain regions 410 may include a first source/drain layer 411 and a second source/drain layer 413. The first source/drain layer 411 may directly contact the substrate 401 and the plurality of fin structures 405, and the second source/drain layer 413 may be a layer formed through a selective epitaxial growth process using the first source/drain layer 411. The second source/drain layer 413 may be connected to the source/drain contacts 430. The source/drain contacts 430 are disposed in the interlayer insulating layer 440 and may be formed of a material such as metal or metal silicide. In an embodiment, the source/drain contacts 430 may include a plurality of layers formed of different materials.

Each of the plurality of gate structures 420 may include a gate spacer 421, a gate insulating layer 422, a gate electrode layer 423, a capping layer 424, and the like. For example, one semiconductor device may be provided by one of the plurality of gate structures 420 and the source/drain regions 410 on both sides thereof.

As illustrated in FIG. 2A, the plurality of fin structures 405 may have a first height H1 and a first width W1. Among the critical dimensions of the plurality of fin structures 405, the first height H1 or the first width W1 may be measured using the semiconductor measurement apparatus.

However, depending on the characteristics of the semiconductor device 400, the height and width of the plurality of fin structures 405 may vary. However, a change in the width of the plurality of fin structures 405 may affect the spectral distribution for measuring the height of the plurality of fin structures 405. Therefore, when the semiconductor measurement apparatus obtains the spectral distribution and measures the heights of the plurality of fin structures 405, a spectral distribution obtained to measure the height may be generated inaccurately due to a change in the width of the plurality of fin structures 405. As a result, errors in measurement may occur.

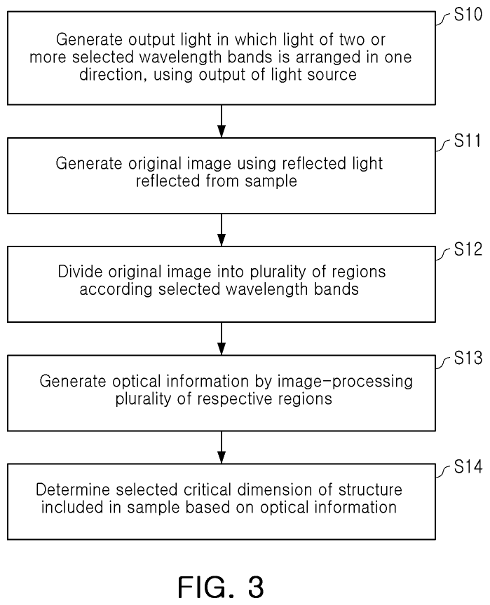

As illustrated in FIG. 2B, the semiconductor device 400A may include a plurality of fin structures 405A having a height greater than the height of the semiconductor device 400. Referring to FIG. 3, the plurality of fin structures 405A may have a second height H2 greater than the first height H1, and as a result, the shapes of the source/drain regions 410A may also vary.

Referring next to FIG. 2C, the semiconductor device 400B may include a plurality of fin structures 405B having a height and a width greater than the height and width of the semiconductor device 400. Referring to FIG. 2C, the plurality of fin structures 405B may have a second width W2 greater than the first width W1, and thus, the shapes of the source/drain regions 410B may also vary.

As illustrated in FIG. 2D, both the height and width of the plurality of fin structures 405C included in the semiconductor device 400C may be increased. Referring to FIG. 2D, the plurality of fin structures 405C may have a second height H2 greater than the first height H1 and a second width W2 greater than the first width W1.

As an example, the spectral distribution obtained to measure the heights of the plurality of fin structures 405 in the semiconductor device 400 may be different from spectral distributions obtained to measure the heights of the plurality of fin structures 405A-405C in the semiconductor devices 400A to 400C.

However, as structures included in the semiconductor devices 400 and 400A-400C are gradually miniaturized, it may be difficult to distinguish whether a difference in spectral distributions obtained from the semiconductor devices 400A to 400C is caused by a change in height or change in width. For example, the plurality of fin structures 405A-405C may be formed by etching partial areas of the substrate 101. When the height of the plurality of fin structures 405A-405C is to be increased, not only the height but also the width of the plurality of fin structures 405A-405C may be increased by an etching process. In this case, it is difficult to distinguish which of the height and width changes of the plurality of fin structures 405A-405C has a greater effect on the change in the spectral distribution output by the semiconductor measurement apparatus. As a result, the required critical dimension may not be accurately determined.

Different critical dimensions, such as height and width, may have different sensitivities to measurement conditions of the semiconductor measurement apparatus. For example, certain azimuth and incident angle conditions may have a higher sensitivity to height than width. In consideration of these characteristics, a required critical dimension may be more accurately measured by acquiring spectral distributions from the semiconductor devices 400A to 400C under various azimuth and incident angle conditions. However, in general, the azimuth angle and incident angle that may be adjusted in a semiconductor measurement apparatus are limited, and a plurality of images are required to obtain optical information corresponding to various azimuth and incident angles, so the above method has limitations.

As described above with reference to FIG. 1, a semiconductor measurement apparatus irradiates light having an optical axis perpendicular to the surface of a sample, and may determine the critical dimension of the structure included in the sample may be determined by accepting the reflected light. Therefore, optical information corresponding to the entire azimuth angle from 0 to 360 degrees may be acquired with one shot, and optical information corresponding to a wide range of incident angles may also be obtained with one shot, depending on the numerical aperture of the objective lens.

In addition, in an embodiment, the incident light output by the lighting unit and incident on the sample through the objective lens includes light of two or more selected wavelength bands, and the light of the selected wavelength bands may be separated from each other and arranged in one direction. Accordingly, optical information corresponding to light of a plurality of selected wavelength bands may be acquired in one shot. Therefore, by obtaining optical information in a short time for accurately determining only the selected critical dimension to be measured regardless of the interaction of critical dimensions that affect each other in structures having a fine critical number, the efficiency of measurement work using a semiconductor measurement apparatus may be improved.

In addition, in an embodiment, the selected critical dimension may be accurately determined. For example, the selected critical dimension may have a specific wavelength band and have high sensitivity to light incident on the sample at a specific azimuth angle and a specific incident angle. In an embodiment, the selected critical dimension to be measured is expected to have high sensitivity at a position corresponding to the azimuth angle and the incident angle, by injecting light in a selected wavelength band expected to have high sensitivity, A selected critical dimension may be accurately determined with a small number of shots.

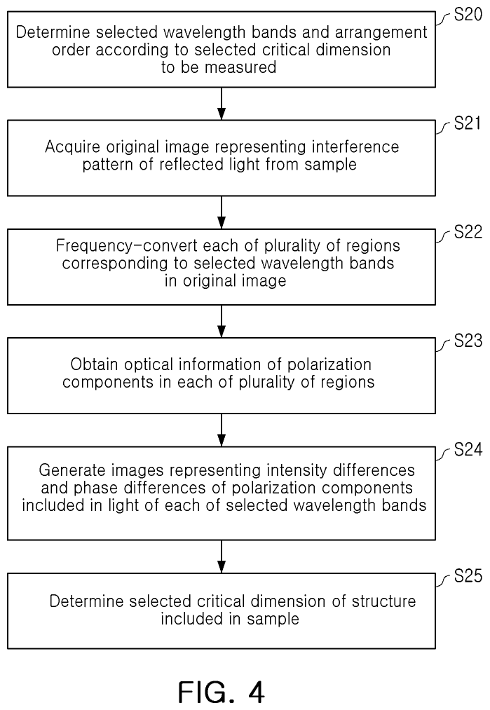

FIG. 3 and FIG. 4 are flowcharts illustrating a measurement method using a semiconductor measurement apparatus according to an embodiment.

Referring to FIG. 3, at operation S10, the measurement method may start with generating output light by the lighting unit of the semiconductor measurement apparatus. For example, the lighting unit may include a light source that emits light in a wide wavelength band, and a light modulator that modulates the light emitted by the light source and generates output light optimized for measurement of a selected critical dimension. The light modulator may generate output light in which light of two or more selected wavelength bands are arranged in one direction by using the output of the light source. The number and type of selected wavelength bands and the arrangement order of the selected wavelength bands may be determined according to a selected critical dimension to be measured from structures included in the sample.

The output light is incident on the sample through the objective lens, and the reflected light reflected from the sample may be incident on the image sensor after passing through the self-interference generator. At operation S11, the image sensor may generate an original image in response to light passing through the self-interference generator. As described above, the original image may be an image representing an interference pattern of polarization components of light separated from each other by the self-interference generator and causing interference again in the image sensor.

The image sensor may output an original image to a controller of the semiconductor measurement apparatus. At operation S12, the controller may divide the original image into a plurality of regions. For example, the original image includes a plurality of regions corresponding to the selected wavelength band included in the output light, and the controller may divide the original image into a plurality of regions according to the selected wavelength band determined at operation S10.

As an example, assuming that light of first to third selected wavelength bands in output light is arranged in one direction, the controller may divide the original image into first to third regions. The first region represents an interference pattern of polarization components of light having a first selected wavelength band, the second region represents an interference pattern of polarization components of light having a second selected wavelength band, and the third region may represent an interference pattern of polarization components of light having a third selected wavelength band.

At operation S13, the controller may generate optical information by processing an image of each of the plurality of regions. The optical information may include an intensity difference and/or a phase difference of polarization components that generate an interference pattern in each of a plurality of regions. Considering the above example, the controller may obtain an intensity difference and/or a phase difference between polarization components of light having the first selected wavelength band by using the first region of the original image. In addition, the controller obtains an intensity difference and/or a phase difference between polarization components of light having a second selected wavelength band using a second region, and obtains an intensity difference and/or a phase difference between polarization components of light having a third selected wavelength band using a third region, and/or a phase difference may be obtained. In this manner, with the original image acquired in one shot, the controller may obtain optical information of polarization components included in light of various wavelength bands reflected from the sample.

At operation S14, the controller may determine the selected critical dimension of the structure included in the sample based on the optical information acquired at operation S13. For example, the controller may determine the selected critical dimension by comparing the reference information previously stored in the library with the optical information acquired at operation S13.

Referring to FIG. 4, at operation S20, the measurement method may begin with determining selected wavelength bands and the arrangement order thereof according to a selected critical dimension to be measured with a semiconductor measurement apparatus. For example, depending on the type of selected critical dimension to be measured, a wavelength band in which light reflected from a sample has high sensitivity, an azimuth angle, an incident angle, and the like may vary.

Assuming a case in which a height and a width of a channel region included in each of the semiconductor elements are to be measured in a state in which a plurality of semiconductor elements are formed on a sample, the height of the channel region has high sensitivity to light in the first wavelength band, and the channel region has high sensitivity to light in the first wavelength band. The width of the region may have high sensitivity to light in the second wavelength band. In an embodiment, the azimuth angle and incident angle with high sensitivity of the height of the channel region may be different from the azimuth angle and incident angle with high sensitivity of the width of the channel region.

In an embodiment, light control data including a wavelength band of light having high sensitivity for each of the critical dimensions, an incident angle, and an azimuth angle may be generated with reference to the measurement result of irradiating light to samples in advance. The controller of the semiconductor measurement apparatus may determine the selected wavelength bands for accurately measuring the selected critical dimension and their arrangement order by referring to the light control data.

When output light generated according to the selected wavelength bands determined at operation S20 and their arrangement order is irradiated to the sample as incident light, the sample may reflect at least a portion of the incident light. At operation S21, the controller may acquire an original image representing an interference pattern of the reflected light from an image sensor that receives the reflected light reflected from the sample. As described above, the self-interference generator is disposed on the path where the reflected light is incident to the image sensor, and the original image may illustrate an interference pattern generated by the self-interference generator.

The original image includes a plurality of regions corresponding to the selected wavelength bands determined at operation S20, and the plurality of regions may be arranged according to the arrangement order determined at operation S20. At operation S22, the controller may frequency-convert each of the plurality of regions, and at operation S23, the controller may obtain optical information of polarization components in each of the plurality of regions by using the frequency conversion. As described above, the optical information may include intensity differences and phase differences of polarization components included in light of a specific wavelength band corresponding to each of a plurality of regions.

At operation S24, Based on the optical information, the controller may generate images representing intensity differences and phase differences of polarization components included in light of each of the selected wavelength bands. The images of operation S24 correspond to each of a plurality of selected wavelength bands, and therefore, the control may generate a first result image illustrating a difference in intensity of polarization components included in light of selected wavelength bands, and a second result image illustrating the phase difference of polarization components included in light of selected wavelength bands. At operation S25, the controller may determine the selected critical dimension of the structure using the first result image and the second result image.

At operation S25, the controller may determine the selection critical size in various ways. In an embodiment, the controller may compare at least one of the first result image and the second result image with reference images included in a pre-constructed library to determine a selected critical dimension. Each of the reference images may be an image generated when the selected critical dimension has a specific value. In an embodiment, the controller may determine one selected wavelength band having high sensitivity in the first result image and/or the second result image, and may also determine the selected critical dimension referring to how the intensity difference and phase difference of polarization components included in light of one selected wavelength band are distributed according to the azimuth angle and the incident angle.

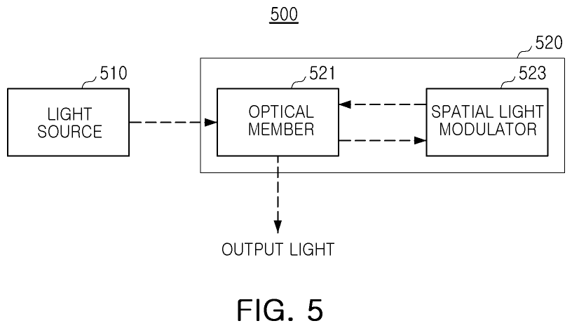

FIG. 5 is a schematic block diagram of a lighting unit included in a semiconductor measurement apparatus according to an embodiment.

Referring to FIG. 5, a lighting unit 500 may include a light source 510 and a light modulator 520. The light source 510 may be a broadband light source that outputs light in a wide wavelength band from an infrared band to an ultraviolet band.

The light modulator 520 may include an optical member 521 and a spatial light modulator 523. The optical member 521 may be an optical component that disperses light output from the light source 510 according to a wavelength band. For example, the optical member 521 may include a prism or a grid structure. When the optical member 521 includes a prism, the prism may be a dispersion prism.

The spatial light modulator 523 may be an optical component that passes through the optical member 521 and adjusts a shape of light dispersed according to a wavelength band. The spatial light modulator 523 may be implemented as a digital micromirror device (DMD), liquid crystal on silicon (LCOS), or liquid crystal display (LCD). The spatial light modulator 523 includes a plurality of optical regions for reflecting or transmitting light dispersed through the optical member 521, and each of the plurality of optical regions may be individually turned on (e.g., activated) and turned off (e.g., deactivated).

A controller included in the semiconductor measurement apparatus together with the lighting unit 500 may determine selected areas and non-selected areas among a plurality of optical regions. The selected areas may be turned on to transmit or reflect light, and the unselected areas may be turned off to transmit or not reflect light. Light transmitted through the selected areas or reflected from the selected areas may pass through the optical member 521 and then be output to the outside of the lighting unit 500 as output light. For example, the output light may be incident on the sample through optical elements included in the semiconductor measurement apparatus.

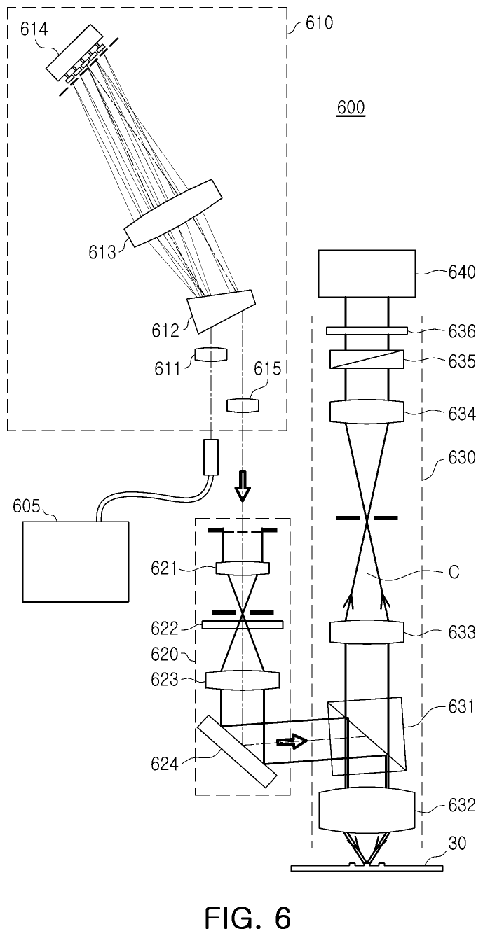

FIG. 6 is a schematic diagram of a semiconductor measurement apparatus according to an embodiment.

Referring to FIG. 6, a semiconductor measurement apparatus 600 may include a light source 605, a light modulator 610, a first optical unit 620, a second optical unit 630, an image sensor 640, and the like. The semiconductor measurement apparatus 600 may further include a controller that controls operations of the light source 605, the light modulator 610, the first optical unit 620, the second optical unit 630, the image sensor 640, and the like.

The light source 605 may output light including a wide wavelength band from an infrared wavelength band to an ultraviolet wavelength band. The light modulator 610 may generate output light by spatially modulating light output from the light source 605. The output light emitted from the light modulator 610 is incident on the sample 30 through the first optical unit 620, and the reflected light reflected from the sample 30 passes through the second optical unit 630 to the image sensor 640 may join.

The light modulator 610 may include an incident lens (input lens) 611, an optical member 612, a focusing lens 613, a spatial light modulator 614, and an emission lens (output lens) 615. Each of the incident lens 611 and the emission lens 615 may be a collimating lens. The optical member 612 may include a prism, a grating structure, etc. that disperses and outputs light passing through the incident lens 611. As illustrated in FIG. 6, light passing through the optical member 612 may be dispersed according to a wavelength band and may be incident to the spatial light modulator 614 through the focusing lens 613. In an embodiment, a cylindrical lens may be disposed between the focusing lens 613 and the spatial light modulator 614 and/or between the optical member 612 and the focusing lens 613.

As illustrated in FIG. 6, the spatial light modulator 614 includes a plurality of optical regions for receiving the light scattered from the optical member 612, and among the plurality of optical regions, some selected areas are turned on. Light is reflected only in the field and may be incident to the focusing lens 613 and the optical member 612 again. In an embodiment, the spatial light modulator 614 may be implemented as a transmissive type instead of the reflective type. The light reflected from the selected areas may be condensed by the optical member 612 and then incident to the first optical unit 620 as output light through the emission lens 615.

The first optical unit 620 may include a first illumination lens 621, an lighting polarization element 622, a second illumination lens 623 and an illumination reflection plate 624. The output light may pass through the first illumination lens 621, the lighting polarization element 622, and the second illumination lens 623, may be reflected by the illumination reflection plate 624, and may enter the beam splitter 631 of the second optical unit 630.

The second optical unit 630 may include a beam splitter 631, an objective lens 632, a first light receiving lens 633, a second light receiving lens 634, a beam displacer 635, an analyzer 636, and the like. The beam splitter 631 reflects some of the output light passing through the first optical unit 620, and the output light reflected from the beam splitter 631 may be incident light to the target region of the sample 30 through the objective lens 632. At least a portion of the incident light may be reflected in the target region of the sample 30 and the reflected light may be incident again to the objective lens 632. The reflected light may pass through the objective lens 632, the beam splitter 631, the first light receiving lens 633 and the second light receiving lens 634 and be incident to the beam displacer 635.

The beam displacer 635 may separate the reflected light into a first polarization component and a second polarization component. For example, the first polarization component may be a P polarization component and the second polarization component may be an S polarization component. The first polarization component and the second polarization component pass through the analyzer and enter the image sensor 640, and the image sensor 640 may generate an original image representing an interference pattern of the first polarization component and the second polarization component. For example, the surface of the image sensor 640 on which the first polarization component and the second polarization component are incident may be disposed at a conjugate position with respect to the back focal plane of the objective lens 632.

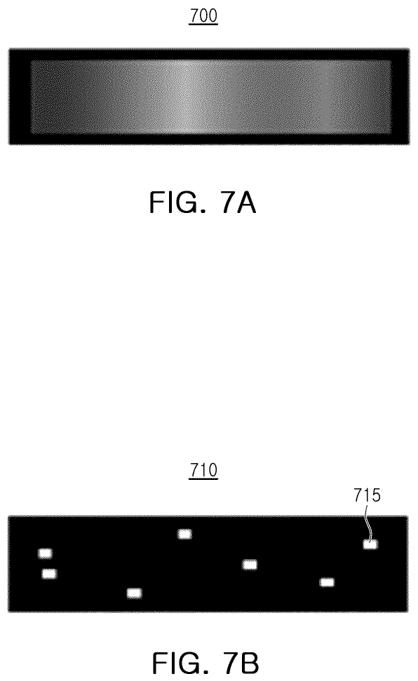

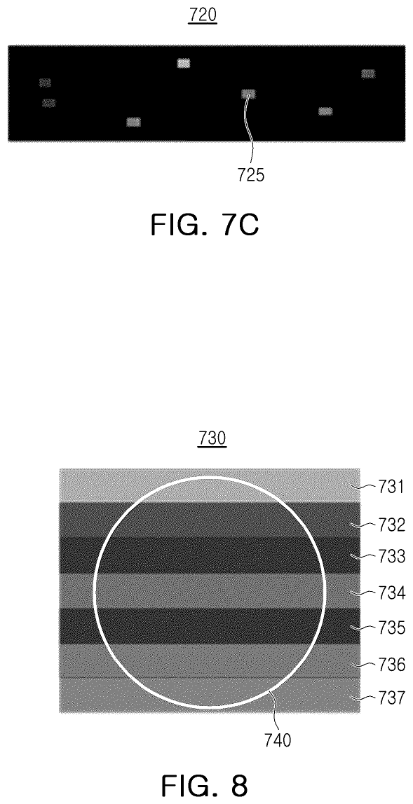

Hereinafter, the operation of the semiconductor measurement apparatus 600 will be described in more detail with reference to FIGS. 7A-7C, 8, 9, and 10.

FIGS. 7A-7C are diagrams illustrating the operation of the semiconductor measurement apparatus according to an embodiment. On the other hand, FIG. 8 is a diagram simply illustrating incident light generated by a semiconductor measurement apparatus according to an embodiment.

FIG. 7A is a diagram illustrating s light 700 output from a light source and passing through an optical member of a light modulator. As illustrated in FIG. 7A, the light 700 passing through the optical member may be dispersed according to a wavelength band.

The light 700 passing through the optical member may enter the spatial light modulator 710. In an embodiment, the spatial light modulator 710 includes a plurality of optical regions arranged in an array, and each of the plurality of optical regions may be individually turned on and off. Referring to FIG. 7B, some selected areas 715 among a plurality of optical regions are turned on, and light 700 passing through the optical member may be reflected only in the selected areas 715. Accordingly, the modulated light reflected from the spatial light modulator 710 may output light of selected wavelength bands 725 to different positions through the selected areas 715 separated from each other as illustrated in FIG. 7C.

In an embodiment described with reference to FIGS. 7A-7C, light having seven selected wavelength bands may be output. Light of the selected wavelength bands 725 included in the modulated light 720 may be spatially modulated while passing through a focusing lens or a cylinder lens. For example, incident light 730 as illustrated in FIG. 8 may be formed by modulating light of each of the selected wavelength bands 725 in a line shape by a focusing lens, a cylinder lens, or the like.

Referring to FIG. 8, the incident light 730 includes light of selected wavelength bands 731-737, and the light of the selected wavelength bands 731-737 may be arranged in one direction. The order in which the light of the selected wavelength bands 731-737 is arranged may be the same as the arrangement order along one direction (vertical direction in FIG. 7C) of the selected wavelength bands 725 described above with reference to FIG. 7C. In detail, each wavelength band of the selected wavelength bands 731-737 included in the incident light 730 and the arrangement order thereof according to the position of the selected areas 715 turned on in the spatial light modulator 710 etc. may be determined. The incident light 730 may be incident on the target region of the sample through the incident region 740 determined according to the numerical aperture of the objective lens.

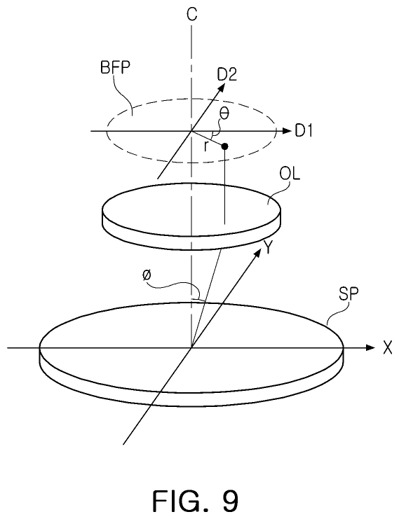

FIG. 9 is a diagram illustrating the operation of a semiconductor measurement apparatus according to an embodiment.

Referring to FIG. 9, the surface of the sample SP may be irradiated with light, and the surface of the sample SP may be defined as an X-Y plane. The optical axis C may extend from the origin of the X-Y plane and may extend along a direction perpendicular to the X-Y plane, and the center of the objective lens OL adjacent to the sample SP may correspond to the optical axis C. The objective lens (OL) includes a front surface facing the sample (SP) and a rear surface located on the opposite side of the sample (SP), and a back focal plane (BFP) may be defined at a predetermined distance from the rear surface of the objective lens OL.

The back focal plane BFP may be a plane defined by the first direction D1 and the second direction D2, and for example, the first direction D1 may be the same as the X-direction of the surface of the sample SP, and the second direction D2 may be the same as the Y-direction. The light passing through the objective lens OL is condensed in the form of a point on the target region of the sample SP, and after being reflected from the target region, it may pass through the objective lens OL and proceed to the back focal plane BFP. As described above, in the semiconductor measurement apparatus according to an embodiment, the light is incident on the sample SP at an entire azimuth angle including 0 degree to 360 degrees, and the incident angle of light incident on the sample SP (φ) range may be determined according to the numerical aperture of the objective lens OL.

In an embodiment, in order to obtain data on a wide range of incident angles possible with one shot performed by an image sensor, and an objective lens OL having a numerical aperture of 0.8 or more and less than 1.0 may be adopted for the semiconductor measurement apparatus. For example, the maximum incident angle of light passing through the objective lens OL may be greater than or equal to 72 degrees and less than 90 degrees. For example, the image sensor may be arranged such that the light receiving surface is located at a position conjugate to the position of the rear focal plane of the objective lens.

When each coordinate included in the focal plane BFP defined by the first direction D1 and the second direction D2 is represented by polar coordinates (r, θ), as illustrated in FIG. 8, the first coordinate (r) may be determined by the angle of incidence q. On the other hand, the second coordinate (θ) is a value indicating how much the coordinate is rotated with respect to the first direction (D1), and may thus be the same as the azimuth angle (θ) of the light incident on the sample (SP), and may have a value of 0 degrees to 360 degrees.

As a result, in the semiconductor measurement apparatus according to an embodiment, with one shot taken while light is reflected from the target region of the sample (SP), data including an interference pattern in the range of an azimuth angle (θ) from 0 degrees to 360 degrees and an incident angle (φ) determined according to the numerical aperture of the objective lens (OL) may be obtained in the form of an image. Therefore, unlike the related art, which required several shots while adjusting the position and angle of the lighting unit that irradiates light on the sample SP or the sample itself, the data required to analyze and measure the target region of the sample (SP) may be acquired with just one shot, and the efficiency of a measurement process using a semiconductor measurement apparatus may be improved.

Incident light 730 passing through the objective lens OL and incident on the target region of the sample SP may include light of a plurality of selected wavelength bands 731-737 arranged in one direction as described above with reference to FIG. 8. Accordingly, light in each of the selected wavelength bands 731-737 may be incident on the target region of the sample SP at an incident angle φ within a predetermined range and an azimuth angle θ within a predetermined range. For example, the incident angle φ and the azimuth angle θ of the light of the first selected wavelength band 731 incident on the target region of the sample SP may be different from the incident angle φ and the azimuth angle θ of the light of the second selected wavelength band 732 incident on the target region of the sample SP.

A selected critical dimension to be measured from structures included in the target region of the sample SP may have high sensitivity to light of a specific wavelength band incident at a specific incident angle and a specific azimuth angle. Therefore, the incident light 730 is such that the light of a specific wavelength band having a high sensitivity of the selected critical dimension is incident on the sample SP at an incident angle and an azimuth angle having a high sensitivity of the selected critical dimension. Selected wavelength bands 731-737 included may be selected and arranged. A method of forming the incident light 730 in this manner will be described later.

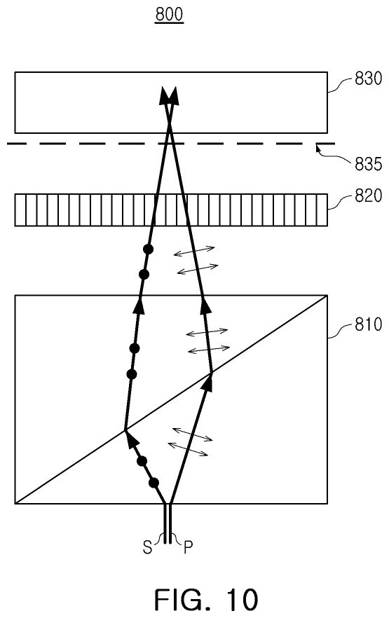

Reflected light reflected from the target region of the sample SP may be incident to the image sensor through the self-interference generator. Hereinafter, it will be described in more detail with reference to FIG. 10.

FIG. 10 is a diagram for explaining a self-interference generator included in a semiconductor measurement apparatus according to an embodiment.

Referring to FIG. 10, the semiconductor measurement apparatus 800 may include a beam displacer 810, an analyzer 820, an image sensor 830, and the like. The reflected light incident on the beam displacer 810 after being reflected from the sample may be separated into a first polarization component P and a second polarization component S by the beam displacer 810. The first polarization component P and the second polarization component S may enter the image sensor 830 through the analyzer 820. In the image sensor 830 receiving the first polarization component (P) and the second polarization component (S), the entrance face 835 may be placed in conjugation position of the back focal plane (BFP) described with reference to FIG. 9.

The first polarization component P and the second polarization component S may enter the image sensor 830 while interfering with each other. The image sensor 830 may output an original image representing an interference pattern of the first polarization component P and the second polarization component S.

As described above, the incident light incident on the sample may include light of selected wavelength bands arranged in one direction. Therefore, the original image output by the image sensor 830 may include a plurality of regions representing interference patterns of the first polarization component P and the second polarization component S included in the light of the respective different selected wavelength bands.

Since the original image includes a plurality of regions representing interference patterns of the first polarization component (P) and the second polarization component (S) included in light of different selected wavelength bands, one original image may be used for two or more wavelengths. Optical information indicating optical characteristics of the first polarization component (P) and the second polarization component (S) of the bands may be obtained. Therefore, the time required to measure the critical dimension of the structure included in the sample may be shortened and the critical dimension of the structure may be more accurately measured.

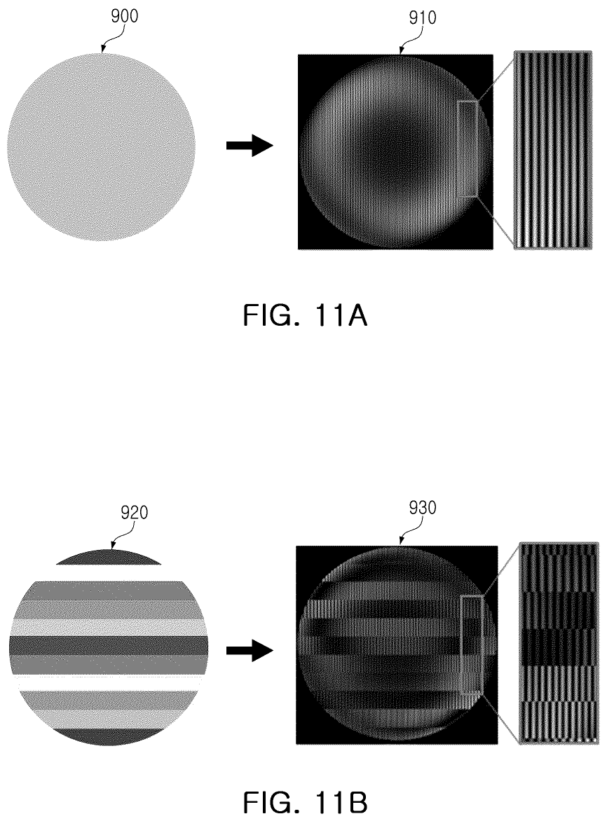

FIGS. 11A and 11B are diagrams illustrating original images acquired by the semiconductor measurement apparatus according to an embodiment.

FIG. 11A is a diagram illustrating an original image 910 generated by an image sensor of a semiconductor measurement apparatus when a lighting unit of the semiconductor measurement apparatus irradiates an incident light 900 of a single wavelength band to a sample at a time. When the incident light 900 incident on the sample in one shot includes light of a single wavelength band, as illustrated in FIG. 11A, interference of polarization components included in the light of the same wavelength band as the incident light 900 An original image 910 representing only the pattern may be created. Therefore, when trying to obtain an interference pattern of polarization components included in light of two or more wavelength bands, two or more shots may be required and the time required for measurement work may increase.

On the other hand, FIG. 11B is a diagram illustrating an original image 930 generated by an image sensor of a semiconductor measurement apparatus when the lighting unit of the semiconductor measurement apparatus radiates incident light 920 including two or more different selected wavelength bands to a sample at once. When the incident light 920 incident on the sample in one shot includes light of two or more selected wavelength bands, the original image 930 may represent an interference pattern of polarization components included in light of each of the selected wavelength bands as illustrated in FIG. 11B.

Referring to FIG. 11B, light of selected wavelength bands in incident light 920 may be arranged in one direction (vertical direction in FIG. 11B). Similarly, in the original image 930, interference patterns of polarization components included in light of selected wavelength bands may be expressed separately along one direction.

The controller of the semiconductor measurement apparatus selects and processes each of a plurality of regions corresponding to the selected wavelength bands in the original image 930, thereby obtaining optical information including an intensity difference and a phase difference of polarization components included in light of each of the selected wavelength bands. Hereinafter, it will be described in more detail with reference to FIGS. 12, 13, 14, 15, and 16.

FIGS. 12 to 16 are diagrams illustrating the operation of a semiconductor measurement apparatus according to an embodiment.

Referring to FIG. 12, an original image 1000 generated by an image sensor of a semiconductor measurement apparatus according to an embodiment may include a plurality of regions arranged in a first direction (vertical direction in FIG. 12). Each of the plurality of regions extends in a second direction (horizontal direction in FIG. 12) crossing the first direction, and may represent an interference pattern of polarization components included in light of one selected wavelength band.

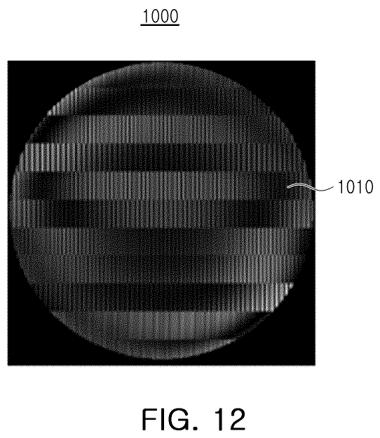

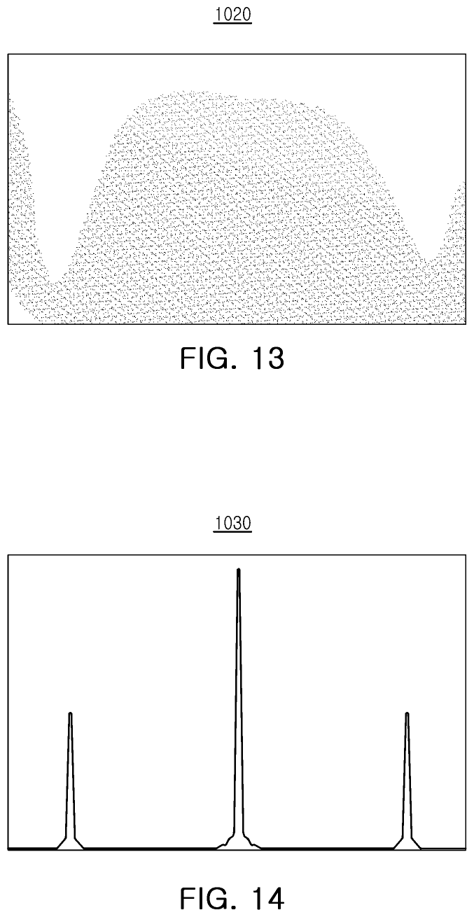

The controller of the semiconductor measurement apparatus may convert each of the plurality of regions into a frequency domain. For example, referring to FIG. 12, the controller may convert image data of a first region 1010 among a plurality of regions into 1D data 1020 as illustrated in FIG. 13. In the 1D data 1020, the horizontal axis may be coordinates along the second direction in which the first region 1010 extends, and the vertical axis may be brightness according to the coordinates in the second direction. The controller may obtain spectral distribution data 1030 as illustrated in FIG. 14 by applying a 1D Fourier transform to the 1D data 1020.

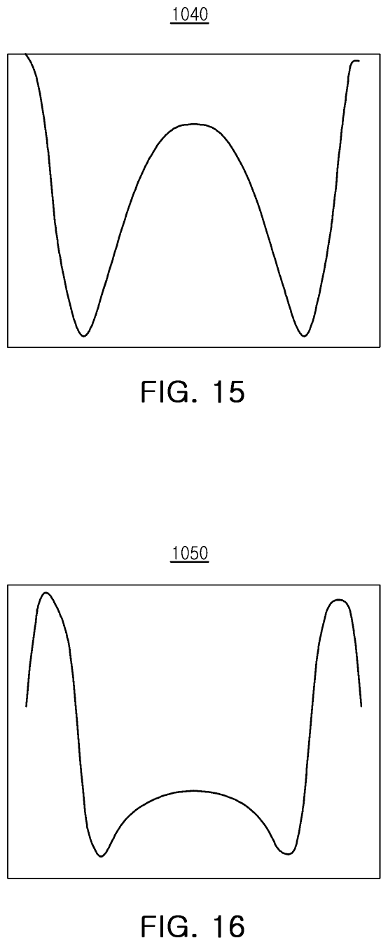

The controller may obtain optical information as illustrated in FIG. 15 and FIG. 16 by applying a one-dimensional inverse Fourier transform to the spectral distribution data 1030. As an example, FIG. 15 may be a graph illustrating intensity differences of polarization components included in light of a wavelength band corresponding to the first region 1010 according to coordinates in the second direction. On the other hand, FIG. 16 may be a graph illustrating phase differences of polarization components included in light of a wavelength band corresponding to the first region 1010 according to coordinates in the second direction.

The controller may obtain optical information about light of each of the selected wavelength bands included in the incident light by performing the operation described with reference to FIGS. 13-16 for each of the plurality of regions. Accordingly, optical information obtained by incident and reflected light of two or more selected wavelength bands on a sample at different azimuth and incident angles may be acquired with one shot, and the speed and accuracy of measurement work may be improved.

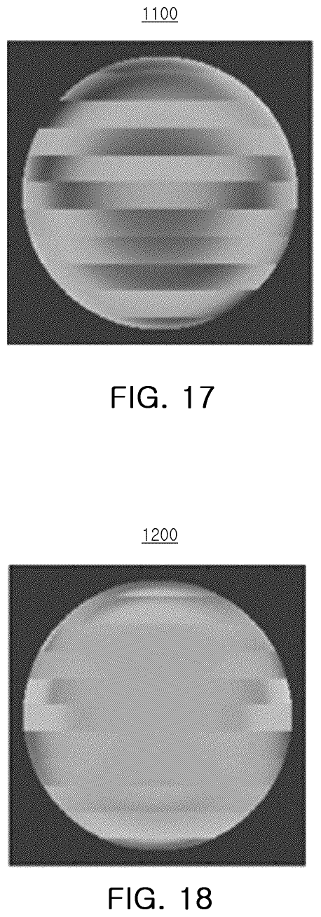

FIG. 17 and FIG. 18 may be drawings illustrating a first result image 1100 and a second result image 1200 generated by applying the operation described with reference to FIGS. 13-16 to each of a plurality of regions included in the original image 1000. The first result image 1100 may be an image representing a difference in intensity of polarization components calculated in each of a plurality of regions, and the second result image 1200 may be an image representing a phase difference between polarization components calculated in each of a plurality of regions.

The controller of the semiconductor measurement apparatus refers to the first result image 1100 and the second result image 1200, and determines the intensity difference and/or phase difference of polarization components according to at least one of a wavelength band of light, an incident angle of light, and an azimuth angle of light. A selection threshold may be determined by comparing the library data with reference data. In this case, the library data may be stored as reference data by classifying the intensity difference and phase difference of the polarization component according to the value of the selected critical dimension when the light is irradiated on the sample according to the wavelength band, incident angle, azimuth angle, etc. of the light.

In an embodiment, the controller of the semiconductor measurement apparatus may compare each of the first result image 1100 and the second result image 1200 with reference images stored in library data to determine a selection critical size. For example, library data may store reference images obtained by irradiating a sample with light of selected wavelength bands having optimal sensitivity for each value of the critical dimensions. Each of the reference images may represent one of an intensity difference and a phase difference of polarization components included in the light irradiated on the sample.

The controller selects the selected wavelength bands having the optimum sensitivity for the selected critical dimension to be measured, and may acquire a first result image 1100 and a second result image 1200 after irradiating the sample with light by arranging the selected wavelength bands with optimal sensitivity. In detail, the selected wavelength bands included in the light irradiated to the sample and the arrangement order thereof in the process of generating a reference image corresponding to the selected critical dimension may be the same as selected wavelength bands included in the light irradiated to the sample in the actual measurement work of measuring the selected critical dimension and their arrangement sequence.

The controller selects selected wavelength bands having optimum sensitivity for a selected critical dimension to be measured, arranges the selected wavelength bands with optimum sensitivity, irradiates the sample with light, and then displays a first result image 1100 and a second result image 1200 may be obtained. In detail, in the process of generating a reference image corresponding to the selected critical dimension, the selected wavelength bands included in the light irradiated to the sample and their arrangement order depend on the light irradiated to the sample in the actual measurement work of measuring the selected critical dimension. It may be the same as the selected wavelength bands included and their arrangement order.

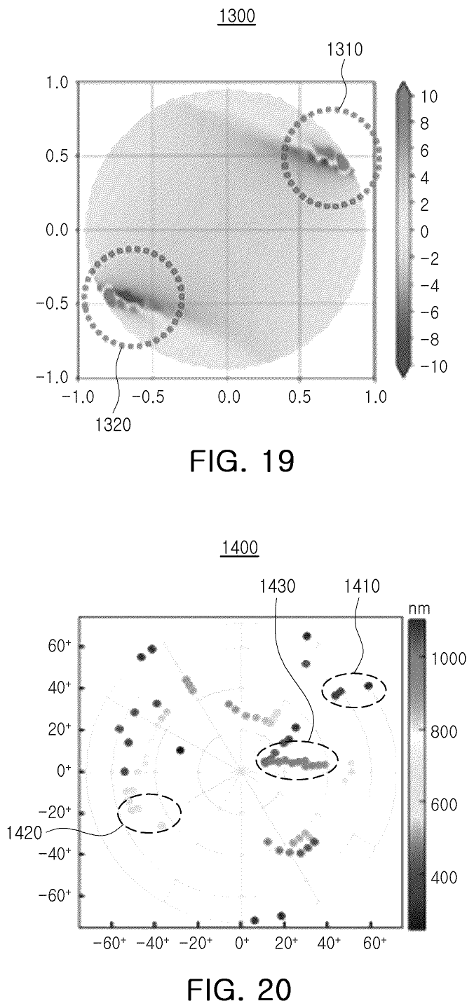

Since the light of the selected wavelength band included in the incident light is arranged in one direction, the light of the one selected wavelength band may be incident to the sample at a certain range of incident angles and azimuth angles. A selected wavelength band having a high sensitivity of a selective critical dimension to be measured from a structure included in a sample, an angle of incidence, and an azimuth angle may differ depending on the type of the selected critical dimension. Therefore, in order to improve the accuracy of measurement work, select wavelength bands are selected according to the type of selected critical dimension to be measured, and light in each of the selected wavelength bands may be incident at an incident angle and incident light having an azimuth angle having high sensitivity for the selected critical dimension may be generated by arranging selected wavelength bands. Hereinafter, it will be described in more detail with reference to FIGS. 19-21.

FIGS. 19-21 are views illustrating a light control method of a semiconductor measurement apparatus according to an embodiment.

FIG. 19 may be an image illustrating a simulation image 1300 for measuring sensitivity of a selected critical dimension from among critical dimensions of structures included in a target region of a sample to light in one first wavelength band. Referring to the simulation image 1300 illustrated in FIG. 19, the selected critical dimension may have high sensitivity in the first region 1310 and the second region 1320 displayed for light of the first wavelength band.

The semiconductor measurement apparatus acquires simulation images by radiating light of not only a first wavelength band but also various wavelength bands other than the first wavelength band to a target region of a sample, and based thereon, may configure sensitivity data 1400 as illustrated in FIG. 20. The sensitivity data 1400 may include image data configured by matching sensitivity of a critical dimension to coordinates defined in a plane perpendicular to an optical axis of reflected light reflected from a target region of a sample. Since the coordinates defined in the plane perpendicular to the optical axis of the reflected light are determined according to the incident angle and the azimuth angle of the reflected light as described above with reference to FIG. 9, the sensitivity data 1400 may be expressed by matching the sensitivity of the critical dimension to a wavelength band of light irradiated onto a sample, an incident angle of light, an azimuth angle of light, and the like. Referring to FIG. 20, the critical dimension may have high sensitivity in regions of different coordinates according to a wavelength band of light incident on a target region of a sample.

For example, the first region 1410 corresponding to the first region 1310 of FIG. 19 and the second region 1420 corresponding to the second region 1320 of FIG. 19 may have high sensitivity to light in the first wavelength band. On the other hand, the third region 1430 may have high sensitivity to light of a second wavelength band longer than the first wavelength band. As illustrated in FIG. 19 and FIG. 20, the light of the first wavelength band may be blue light, and the light of the second wavelength band may be red light.

The controller of the semiconductor measurement apparatus may control the lighting unit with reference to the sensitivity data 1400 illustrated in FIG. 20. For example, when the selected critical dimension to be measured from the structure of the sample in the actual measurement operation is the critical dimension corresponding to the sensitivity data 1400 as illustrated in FIG. 20, the controller may adjust output light output by the lighting unit with reference to the sensitivity data 1400. For example, the number of selected wavelength bands included in the output light, the type of the selected wavelength bands, the arrangement order of the selected wavelength bands, etc. may be determined according to the sensitivity data 1400.

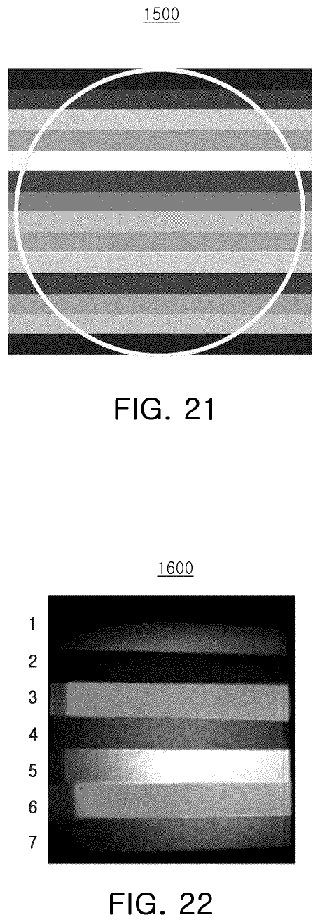

Referring to the sensitivity data 1400 illustrated in FIG. 20, light of a first wavelength band corresponding to blue light is disposed in a first region 1410 and a second region 1420, and may be advantageous to measure the selected critical dimension if the light of the second wavelength band corresponding to the red light is disposed in the third region 1430. Accordingly, the lighting unit may output an incident light 1500 as illustrated in FIG. 21. Referring to FIG. 21, blue light of a first wavelength band is disposed in a line shape in an area corresponding to each of a first region 1410 and a second region 1420, and in an area corresponding to a third region 1430. Red light of the second wavelength band may be arranged in a line shape. In this manner, the sensitivity data 1400 may be configured in advance by executing simulations according to the type of selected critical dimensions, and the incident light 1500 may be generated with reference to the simulation, thereby minimizing the influence of the interaction between the critical dimensions in the measurement task.

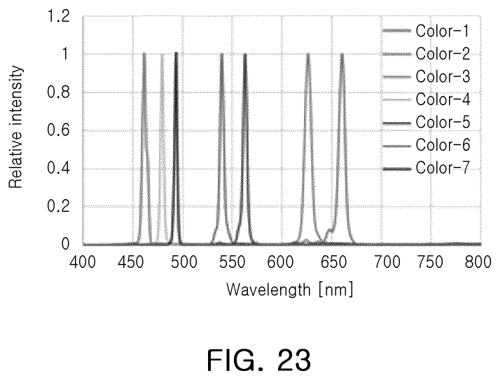

FIG. 22 and FIG. 23 are diagrams illustrating the operation of the semiconductor measurement apparatus according to an embodiment.

FIG. 22 may be a diagram illustrating an output light 1600 actually output by a lighting unit of a semiconductor measurement apparatus according to an embodiment. On the other hand, FIG. 23 may be a spectral distribution illustrating the intensity of each of the selected wavelength bands included in the output light 1600.

As illustrated in FIG. 22, the lighting unit may generate output light 1600 in which seven selected wavelength bands are arranged in one direction. For example, the third selected wavelength band and the sixth selected wavelength band may correspond to a red wavelength band, and the fourth selected wavelength band and the seventh selected wavelength band may correspond to a blue wavelength band. Accordingly, as illustrated in FIG. 23, a wavelength at which a peak appears in light of the third selected wavelength band may be similar to a wavelength at which a peak appears in light in the sixth selected wavelength band. Similarly, a wavelength at which a peak appears in light of the fourth selected wavelength band may be similar to a wavelength at which a peak appears in light in the seventh selected wavelength band.

As illustrated in FIG. 22 and FIG. 23, light in each of the selected wavelength bands has maximum intensity at one wavelength, but this may vary depending on the embodiment. For example, in light of one selected wavelength band, peaks may appear at two or more different wavelengths.

The configuration of the output light 1600 may vary depending on a wavelength band having a high sensitivity of a selected critical dimension to be measured, an incident angle and an azimuth angle, and the like. In one example, the selection threshold dimension to be measured is arranged along a line in the plane in which the output light 1600 is represented and is high for first and second different wavelength bands at different first and second positions. In the case of sensitivity, light having peaks in the first wavelength band and the second wavelength band may be output to the corresponding line.

As set forth above, according to an embodiment, an original image corresponding to an azimuth angle of 0 degrees to 360 degrees may be acquired in one shot, and optical information indicating optical characteristics of polarization components of light may be acquired in the original image. Photography to obtain an original image is performed while incident light in which two or more different wavelength bands of light are arranged in one direction is irradiated to the sample, and optical properties in several wavelength bands may be obtained simultaneously with one shot. Therefore, the time required for measurement work to determine a selected critical dimension to be measured may be reduced, and the selected critical dimension may be accurately determined regardless of interaction of critical dimensions that affect each other in the process.

While example embodiments have been illustrated and described above, it will be apparent to those skilled in the art that modifications and variations could be made without departing from the scope of the present disclosure as defined by the appended claims and their equivalents.

What is claimed is:

1. A semiconductor measurement apparatus comprising:
a lighting unit comprising a light source, and a light modulator configured to decompose a light output by the light source into a plurality of wavelength bands and generate output light in which at least two selected wavelength bands is arranged in one direction;
a first optical unit comprising at least one illumination polarizing element disposed in a path of the output light;
a second optical unit comprising a beam splitter, an objective lens configured to allow light having passed through the first optical unit to be incident onto a sample, and a self-interference generator disposed on a path of a reflected light from the sample;
a sensor disposed on a rear end of the second optical unit and configured to output an original image representing an interference pattern of light having passed through the self-interference generator; and
a controller configured to process the original image and determine a selected critical dimension from among a plurality of critical dimensions of a structure included in the sample.

2. The semiconductor measurement apparatus of claim 1, wherein the self-interference generator comprises a Nomarski prism and at least one polarizer sequentially disposed in the path of the reflected light.

3. The semiconductor measurement apparatus of claim 1, wherein the light modulator comprises an optical member configured to decompose the light output by the light source into the plurality of wavelength bands, and a spatial light modulator configured to generate the output light by passing the light having passed through only a selected partial area of the optical member, and
the optical member is further configured to emit the output light generated by the spatial light modulator to the first optical unit.

4. The semiconductor measurement apparatus of claim 3, wherein the optical member comprises at least one of a prism or a grating structure.

5. The semiconductor measurement apparatus of claim 3, wherein the light modulator comprises a cylinder lens and a focusing lens disposed between the optical member and the spatial light modulator.

6. The semiconductor measurement apparatus of claim 5, wherein the light modulator comprises a first cylinder lens disposed between the optical member and the focusing lens, and a second cylinder lens disposed between the focusing lens and the spatial light modulator.

7. The semiconductor measurement apparatus of claim 3, wherein the spatial light modulator comprises at least one of a digital micromirror device (DMD), a liquid crystal on silicon (LCoS), or a liquid crystal display (LCD).

8. The semiconductor measurement apparatus of claim 1, wherein the original image represents the interference pattern generated from the light of the at least two selected wavelength bands and comprises a plurality of regions arranged along the one direction.

9. The semiconductor measurement apparatus of claim 8, wherein the controller is further configured to convert each of the plurality of regions into a frequency domain and acquire spectral distribution data in which at least one peak appears due to interference of polarization components included in light of the at least two selected wavelength bands, and
wherein the controller is further configured to obtain an intensity difference and a phase difference of the polarization components included in light of each of the at least two selected wavelength bands by inversely frequency transforming the spectral distribution data of each of the plurality of regions.

10. The semiconductor measurement apparatus of claim 1, wherein the objective lens has a numerical aperture of at least 0.8 and less than 1.0.

11. The semiconductor measurement apparatus of claim 1, wherein the sensor is an image sensor, and a surface of the image sensor is located in a conjugation position of a back focal plane of the objective lens.

12. The semiconductor measurement apparatus of claim 1, wherein the light output from the light source comprises a wavelength band from ultraviolet to infrared.

13. A semiconductor measurement apparatus comprising:
a lighting unit configured to generate output light in which light of at least two selected wavelength bands are arranged in a first direction;
a first optical unit disposed on a path of the output light;
a second optical unit comprising an objective lens disposed on a path of an incident light having passed through the first optical unit and a path of a reflected light in which a sample reflects the incident light;
an image sensor configured to generate a self-interference image representing an interference pattern of light having passed through the second optical unit; and
a controller configured to measure a selected critical dimension among a plurality of critical dimensions of a structure included in the sample by using the self-interference image,
wherein the controller is configured to determine the selected wavelength bands of the output light and an arrangement order of the selected wavelength bands in the first direction, based on the selected critical dimension.

14. The semiconductor measurement apparatus of claim 13, wherein the lighting unit comprises a light source, an optical member configured to refract and output light output from the light source, and a spatial light modulator having a plurality of optical regions configured to reflect or transmit an output of the optical member therethrough.

15. The semiconductor measurement apparatus of claim 14, wherein the controller is further configured to determine the selected wavelength bands and the arrangement order of the selected wavelength bands by activating a selected area of a portion of the plurality of optical regions and deactivating an unselected area.

16. The semiconductor measurement apparatus of claim 15, wherein the controller is further configured to determine the selected wavelength bands and the arrangement order of the selected wavelength bands based on a relationship between coordinates defined in a plane, perpendicular to an optical axis of the reflected light, and sensitivity to the plurality of critical dimensions.

17. The semiconductor measurement apparatus of claim 16, wherein the coordinates are defined by an angle of incidence and an angle of reflection of the reflected light.

18. A semiconductor measurement apparatus comprising:
a lighting unit configured to generate an output light based on sensitivity data obtained by matching wavelength bands of light, an incident angle of light, and an azimuth angle of light with a sensitivity of a critical dimension;
an image sensor configured to generate an original image based on receiving a reflected light in which the output light is reflected from a target region of a sample; and
a controller configured to obtain optical information about polarization components included in the reflected light from each of a plurality of regions in the original image, and determine a selected critical dimension among a plurality of critical dimensions of structures included in the target region based on the optical information.

19. The semiconductor measurement apparatus of claim 18, wherein the plurality of regions represent an interference pattern of polarization components included in light of a plurality of selected wavelength bands included in the output light.

20. The semiconductor measurement apparatus of claim 19, wherein the controller is further configured to obtain an intensity difference and a phase difference of the polarization components included in the light of the plurality of selected wavelength bands, as the optical information.
